(19) United States
(12) Patent Application Publication
(10) Pub. No.: US 2013/0313309 A1
(43) Pub. Date: Nov. 28, 2013

(54) CONDUCTIVE BONDING MATERIAL, METHOD OF MANUFACTURING THE SAME, AND METHOD OF MANUFACTURING ELECTRONIC DEVICE

(71) Applicant: FUJITSU LIMITED, Kawasaki-shi (JP)

(72) Inventors: Masayuki KITAJIMA, Yokohama (JP); Takatoyo YAMAKAMI, Nagano (JP); Takashi KUBOTA, Chikuma (JP); Kuniko ISHIKAWA, Nagano (JP)

(21) Appl. No.: 13/852,289

(22) Filed: Mar. 28, 2013

(30) Foreign Application Priority Data
May 28, 2012 (JP) 2012-121202

(51) Int. Cl. H01L 21/64; B23K 35/02

(52) U.S. Cl. CPC H01L 21/64; B23K 35/0244; B23K 35/025
USPC 228/180.5; 148/24; 75/354; 75/345; 428/576; 428/546

(57) ABSTRACT

A conductive bonding material includes: a solder component including a metal foamed body of a first metal having at least one pore, the pore absorbs melted first metal when the metal foamed body is heated at a temperature higher than the melting point of the first metal, and a second metal having a melting point lower than the melting point of the first metal.

### CROSS-REFERENCE TO RELATED APPLICATION

This application is based upon and claims the benefit of priority of the prior Japanese Patent Application No. 2012-121202, filed on May 28, 2012, the entire contents of which are incorporated herein by reference.

### FIELD

The embodiments discussed herein are related to a conductive bonding material, an electronic part manufactured using the conductive bonding material, and an electronic device including the electronic part.

### BACKGROUND

An electronic part that includes an electronic component, such as a chip component or a semiconductor component, on a circuit board is sometimes mounted on a large circuit board (hereinafter also referred to as a printed circuit board), such as a motherboard or a system board. The component, such as a chip component, of the electronic part is mounted on the circuit board using a solder paste as a conductive bonding material. This mounting is referred to as first mounting. The first mounting may be performed by reflow heating (first reflow). After the component, such as a chip component, is first mounted on the circuit board in this manner, the electronic part except electrodes and some elements is sometimes sealed with a sealing resin. Such an electronic part sealed with a sealing resin is sometimes referred to as a “resin module component”.

In an electronic device, such an electronic part is mounted on a printed circuit board using a solder paste as a conductive bonding material. This mounting is referred to as second mounting. The second mounting may be performed by reflow heating (second reflow).

The second reflow heating of a resin module component may re-melt a conductive bonding material in the resin module component. The re-melted conductive bonding material may flow through a narrow gap in the electronic part to cause a short circuit between electrodes. The narrow gap may be formed by cracking of the sealing resin or detachment of the sealing resin from the component, such as a chip component, caused by the volume expansion of the conductive bonding material melted in the second reflow heating and the resulting stress.

Thus, the reduction of volume expansion and the resulting stress caused by the re-melting of the conductive bonding material in the second reflow heating is under study. For example, a composition that contains foam solders containing a first material for use in bonding between IC and an external structure. The foam solder has a form selected from a cellular foaming form and a netlike foaming form and can relieve thermal stress (including impact and dynamic load) between the foam solder and a substrate to which the foam solder is bonded. The composition is not used to mount a resin module component. The foam solder aims to relieve the thermal stress and desirably maintains a hollow structure even after second reflow heating (after second mounting).

Thus, there is a demand for a conductive bonding material that can first mount a component, such as a chip component or a semiconductor component, on a circuit board by first reflow heating and reduce volume expansion and the resulting stress caused by the re-melting of the conductive bonding material in second reflow heating.

The followings are reference documents. [Document 1] Japanese Laid-open Patent Publication No. 2009-515711.

### SUMMARY

According to an aspect of the invention, a conductive bonding material includes a solder component including: a metal foamed body of a first metal having at least one pore, the pore absorbs melted first metal when the metal foamed body is heated at a temperature higher than the melting point of the first metal, and a second metal having a melting point lower than the melting point of the first metal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a schematic cross-sectional view of an electronic part having a gap formed by second reflow heating;

FIG. 1B is a schematic cross-sectional view of the electronic part in which a melted conductive bonding material enters the gap to cause a short circuit between electrodes;

FIG. 2A is an explanatory view of the principle upon which volume expansion and the resulting stress due to the re-melting of a conductive bonding material containing first metal particles and second metal particles can be reduced (initial state). The first metal particles can be re-melted by second reflow heating;

FIG. 2B is an explanatory view of the principle upon which volume expansion and the resulting stress due to the remelting of a conductive bonding material containing first metal particles and second metal particles can be reduced (first reflow heating state). The first metal particles can be remelted by second reflow heating;

FIG. 2C is an explanatory view of the principle upon which volume expansion and the resulting stress due to the remelting of a conductive bonding material containing first metal particles and second metal particles can be reduced (second reflow heating state). The first metal particles are remelted by second reflow heating;

FIG. 3A is an explanatory view of the principle upon which volume expansion and the resulting stress due to the re-melting of a conductive bonding material containing coated particles can be reduced (initial state). Each of the coated particles includes a second metal layer on the surface of a first metal particle. The first metal particle can be re-melted by second reflow heating;

FIG. 3B is an explanatory view of the principle upon which volume expansion and the resulting stress due to the remelting of a conductive bonding material containing coated particles can be reduced (first reflow heating state). Each of the coated particles includes a second metal layer on the surface of a first metal particle. The first metal particle can be re-melted by second reflow heating;

FIG. 3C is an explanatory view of the principle upon which volume expansion and the resulting stress due to the remelting of a conductive bonding material containing coated particles can be reduced (second reflow heating state). Each of the coated particles includes a second metal layer on the surface of a first metal particle. The first metal particles are re-melted by second reflow heating;

FIG. 4A is a photograph of a first metal powder having pores;

FIG. 4B is a fragmentary enlarged photograph of FIG. 4A;

FIG. 4C is a photograph of first metal particles after atomizing treatment;

FIG. 5 is a flow chart of a method for manufacturing an electronic part according to one embodiment and a method for manufacturing an electronic device according to one embodiment;

FIG. 6A is a schematic top view illustrating a method for manufacturing an electronic part according to one embodiment and a method for manufacturing an electronic device according to one embodiment;

FIG. 6B is a schematic top view illustrating a method for manufacturing an electronic part according to one embodiment and a method for manufacturing an electronic device according to one embodiment;

FIG. 6C is a schematic top view illustrating a method for manufacturing an electronic part according to one embodiment and a method for manufacturing an electronic device according to one embodiment;

FIG. 6D is a schematic top view illustrating a method for manufacturing an electronic part according to one embodiment and a method for manufacturing an electronic device according to one embodiment;

FIG. 6E is a schematic top view illustrating a method for manufacturing an electronic part according to one embodiment and a method for manufacturing an electronic device according to one embodiment;

FIG. 6F is a schematic top view illustrating a method for manufacturing an electronic part according to one embodiment and a method for manufacturing an electronic device according to one embodiment;

FIG. 6G is a schematic top view illustrating a method for manufacturing an electronic part according to one embodiment and a method for manufacturing an electronic device according to one embodiment;

FIG. 7A is a schematic cross-sectional view illustrating a method for manufacturing an electronic part according to one embodiment and a method for manufacturing an electronic device according to one embodiment;

FIG. 7B is a schematic cross-sectional view illustrating a method for manufacturing an electronic part according to one embodiment and a method for manufacturing an electronic device according to one embodiment;

FIG. 7C is a schematic cross-sectional view illustrating a method for manufacturing an electronic part according to one embodiment and a method for manufacturing an electronic device according to one embodiment;

FIG. 7D is a schematic cross-sectional view illustrating a method for manufacturing an electronic part according to one embodiment and a method for manufacturing an electronic device according to one embodiment;

FIG. 7E is a schematic cross-sectional view illustrating a method for manufacturing an electronic part according to one embodiment and a method for manufacturing an electronic device according to one embodiment;

FIG. 7F is a schematic cross-sectional view illustrating a method for manufacturing an electronic part according to one embodiment and a method for manufacturing an electronic device according to one embodiment;

FIG. 7G is a schematic cross-sectional view illustrating a method for manufacturing an electronic part according to one embodiment and a method for manufacturing an electronic device according to one embodiment;

FIG. 8A is a photograph indicating the evaluation results of the occurrence of solder melting in an electronic part after second mounting in Example 1;

FIG. 8B is a fragmentary enlarged photograph of FIG. 8A;

FIG. 9A is a photograph indicating the evaluation results of the occurrence of solder melting in an electronic part after second mounting in Comparative Example 1;

FIG. 9B is a fragmentary enlarged photograph of FIG. 9A;

FIG. 10 is a photograph of a first metal particle having pores manufactured by a foam melting method; and

FIG. 11 is a table of measurement results for a conductive bonding material produced in examples.

### DESCRIPTION OF EMBODIMENTS

Conductive Bonding Material

A conductive bonding material according to one embodiment contains a solder component and optionally a flux component and other components.

<Solder Component>

The solder component contains a first metal body and a second metal.

The solder component preferably contains particles of the first metal (hereinafter also referred to as “first metal particles”) and particles of the second metal (hereinafter also referred to as “second metal particles”). Alternatively, the solder component preferably contains coated particles, which are first metal particles coated with the second metal.

<<First Metal Body>>

The first metal body is made of the first metal and has at least one pore for absorbing melted first metal on heating to a temperature higher than the melting point of the first metal. The shape, size, structure, and material of the first metal body are not particularly limited and may be appropriately selected for each purpose. The first metal body may have a particle shape. For example, the first metal body is globular, spherical, or ellipsoidal. The first metal body may have a monolayer structure or a multilayer structure.

The material of the first metal body is preferably one of a Sn—Bi—X alloy and a Sn—Cu—X alloy, wherein X is Ag, Ni, Zn, Pd, or In. Among these, a Sn—Bi—Ag alloy and a Sn‘3Cu—Ag alloy are particularly preferred in terms of solderability.

The Sn—Bi—Ag alloy may be a Sn-58.0Bi-1.0Ag alloy, in which Sn is a main component, Bi constitutes approximately 58.0% by mass, and Ag constitutes approximately 1.0% by mass.

The Sn—Cu—Ag alloy may be a Sn-0.5Cu-3.0Ag alloy, in which Sn is the main component, Cu constitutes approximately 0.5% by mass, and Ag constitutes approximately 3.0% by mass.

The volume-average particle size of the first metal particles is preferably in the range of 0.5 to 50 μm, more preferably 10 to 40 μm. When the volume-average particle size is less than 0.5 μm, it is difficult to manufacture the first metal particles having a small diameter, and it is difficult for the first metal particles to constitute approximately 30% by mass of the solder component, possibly resulting in poor applicability of the conductive bonding material to the circuit board.

The volume-average particle size may be determined with a particle size distribution analyzer by a laser diffraction scattering method.

The melting point of the first metal is preferably 150° C. or more and 230° C. or less, more preferably in the range of 160° C. to 220° C. A melting point of more than 230° C. results in an increase in second reflow heating temperature, which may cause re-melting of the conductive bonding material.

The melting point may be measured by differential scanning calorimetry (DSC).

—Pore—

On heating to a temperature higher than the melting point of the first metal, the pore absorbs melted first metal.

The pore refers to a vacant space within the first metal particles. The shape, size, and structure of the pore are not particularly limited and may be appropriately selected for each purpose. The pore may have a porous, netlike, cellular, or hollow shape. Two or more of the pores surrounded by the first metal may communicate with each other or not.

The pore is present within the first metal particles and has no opening on the surfaces of the first metal particles. The interior of the pore is preferably under reduced pressure or vacuum so as to reduce volume expansion and the resulting stress caused by the re-melting of the conductive bonding material in second reflow heating.

The presence of the pore may be detected by the image analysis of a photograph of a cross section of the first metal particles taken with an optical microscope or a scanning electron microscope.

The pore may have any volume that allows stress due to the thermal expansion of the conductive bonding material in second reflow heating to be relieved. Thus, the pore volume may be appropriately determined for each purpose and is preferably 5% by volume to 30% by volume, more preferably 10% by volume to 20% by volume, of the first metal particles. A pore volume of less than 5% by volume may result in an insufficient reduction of volume expansion and the resulting stress caused by the re-melting of the conductive bonding material in second reflow heating. A pore volume of more than 30% by volume may result in low strength of the first metal particles because of the excessively high volume percentage of the pore.

The pore volume may be determined as described below. First, the volume of the first metal particles is measured before melting. The volume of the first metal particles is also measured after melting. The pore volume of the first metal particles can be calculated from the measured volumes using the following formula.

Pore volume (μm³)=Volume of first metal particles before melting−Volume of first metal particles after melting

The first metal particles are not particularly limited and may be appropriately produced or may be a commercial product. A method for producing the first metal particles will be described below in connection with a method for producing a conductive bonding material.

<Second Metal>

The second metal has a lower melting point than the first metal. The shape, structure, and material of the second metal are not particularly limited and may be appropriately selected for each purpose. The second metal may have a particle shape. For example, the second metal is globular, spherical, or ellipsoidal. The second metal may have a monolayer structure or a multilayer structure.

The second metal may be a Sn—Bi alloy or a Sn—Bi—Y alloy, wherein Y is Ag, Ni, Zn, Pd, or In.

The Sn—Bi alloy may be a Sn-58.0Bi alloy, in which Sn is a main component, and Bi constitutes approximately 58.0% by mass. The Sn—Bi—Y alloy may be a Sn—Bi—Ag alloy. The Sn—Bi—Ag alloy may be a Sn-57.0Bi-1.0Ag alloy, in which Sn is a main component, Bi constitutes approximately 57.0% by mass, and Ag constitutes approximately 1.0% by mass.

The volume-average particle size of the second metal particles is preferably 10 μm or more, more preferably in the range of 10 to 60 μm, still more preferably 10 to 40 μm.

The volume-average particle size may be determined with a particle size distribution analyzer by a laser diffraction scattering method.

The melting point of the second metal is lower than the melting point of the first metal and is preferably less than 150° C., more preferably in the range of 80° C. to 140° C. A melting point of 150° C. or more results in a decrease in the melting point difference between the first metal and the second metal, making low-temperature bonding difficult.

The melting point may be measured by differential scanning calorimetry (DSC).

The second metal particles may be appropriately produced or may be a commercial product. A method for producing the second metal particles may be an atomizing method. In accordance with the atomizing method, melted second metal sprayed through a nozzle is scattered by high-speed collision with a spray medium (gas or liquid), and the resulting droplets are cooled and coagulate into particles.

The solder component preferably contains a mixture of the first metal particles and the second metal particles.

The mass ratio (A:B) of the first metal particles (A) to the second metal particles (B) is preferably in the range of 20:80 to 50:50, more preferably 30:70 to 50:50.

When the first metal particles constitute less than 20% by mass, this results in a low pore volume and insufficient relief of stress caused by the thermal expansion of the solder component in second reflow heating. When the first metal particles constitute more than 50% by mass, this results in low soldering strength.

The solder component may contain coated particles, which are first metal particles having at least one pore coated with the second metal. This is preferred because the conductive bonding material is composed of coated particles alone.

The coated particles may be appropriately produced or may be a commercial product.

The first metal particles having at least one pore in the coated particles may be the same as the first metal particles in the mixture of the first metal particles and the second metal particles.

The average particle size of the first metal particles is preferably 40 μm or less, more preferably in the range of 20 to 40 μm.

The average thickness of a layer of the second metal is preferably 5 μm or more, more preferably in the range of 5 to 20 μm. An average thickness of less than 5 μm results in a decrease in the amount of second metal, possibly making low-temperature bonding at 150° C. or less difficult.

The layer of the second metal covering each of the first metal particles may be formed by electro less plating.

The solder component content of the conductive bonding material is not particularly limited and may be appropriately selected for each purpose. The solder component content is preferably in the range of 50% by mass to 95% by mass, more preferably 70% by mass to 90% by mass.

<Flux Component>

The flux component is not particularly limited and may be appropriately selected for each purpose. The flux component is preferably at least one of an epoxy flux material and a rosin flux material. Among these, an epoxy flux material is particularly preferred because hardened epoxy resin can improve the bonding strength of the conductive bonding material.

—Epoxy Flux Material—

The epoxy flux material contains an epoxy resin, a carboxylic acid, a solvent, and optional components.

The epoxy resin is not particularly limited and may be appropriately selected for each purpose. Examples of the epoxy resin include thermosetting epoxy resins, such as bisphenol An epoxy resins, bisphenol F epoxy resins, novolak epoxy resins, and modified epoxy resins thereof. These epoxy resins may be used alone or in combination.

The carboxylic acid is not particularly limited and may be appropriately selected for each purpose. Examples of the carboxylic acid include saturated aliphatic dicarboxylic acids, unsaturated aliphatic dicarboxylic acids, alicyclic dicarboxylic acids, carboxylic acids containing an amino group, carboxylic acids containing a hydroxy group, heterocyclic dicarboxylic acids, and mixtures thereof. More specifically, the carboxylic acid may be succinic acid, glutaric acid, adipic acid, azelaic acid, dodecanedioic acid, itaconic acid, mesaconic acid, cyclobutanedicarboxylic acid, L-glutamic acid, citric acid, malic acid, thiopropionic acid, thiodibutyric acid, or dithioglycolic acid.

Examples of the solvent include alcohols, such as methanol, ethanol, and propanol, ethylene glycol solvents, diethylene glycol monohexyl ether, and octanediol.

Examples of the optional components include additive agents, such as a thixotropic agent, a chelator, a surfactant, and an antioxidant.

The epoxy flux material is not particularly limited and may be appropriately synthesized or may be a commercial product.

—Rosin Flux Material—

The rosin flux material contains a rosin resin, an activator, a solvent, and optional components.

The rosin resin may be mainly composed of a natural rosin resin or a modified rosin resin. Examples of the modified rosin resin include polymerized rosins, hydrogenated rosins, phenolic resin modified rosins, and maleic acid modified rosins.

The activator may be any component that can reduce an oxide, a sulfide, a hydroxide, a chloride, a sulfate, and/or a carbonate on a metal to clean the metal, and may be appropriately selected for each purpose. For example, the activator is diethylamine hydrochloride or diethylamine oxalate.

Examples of the solvent include ethylene glycol solvents, diethylene glycol monohexyl ether, and octanediol.

Examples of the optional components include a thixotropic agent, a chelator, a surfactant, and an antioxidant.

The rosin flux material is not particularly limited and may be appropriately synthesized or may be a commercial product.

The flux component content of the conductive bonding material is not particularly limited and may be appropriately selected for each purpose. The flux component content is preferably in the range of 8% by mass to 14% by mass.

<Other Components>

In addition to the metal component and the flux component, the conductive bonding material may contain optional components. Examples of the optional components include a metal adsorbent, a dispersant, and an antioxidant.

The metal adsorbent is not particularly limited and may be appropriately selected for each purpose. Examples of the metal adsorbent include imidazoles, benzimidazoles, alkylbenzimidazoles, benzotriazoles, and mercaptobenzothiazoles.

A conductive bonding material according to one embodiment may be applied by printing to an electrode pad on a circuit board in an electronic part that includes a component, such as a chip component or a semiconductor component, to be sealed with a sealing resin. First reflow heating of the conductive bonding material applied to the electrode pad on the circuit board allows the electrode pad to be connected to electrodes of the component, such as a chip component or a semiconductor component. The component, such as a chip component or a semiconductor component, on the circuit board is then sealed with a sealing resin.

The electronic part thus sealed is then mounted on a large circuit board, such as a motherboard or a system board. Terminals of the electronic part are connected to lead terminals of the circuit board by second reflow heating of the conductive bonding material. The second reflow heating may re-melt the conductive bonding material of the electronic part. The re-melted conductive bonding material may enter a gap in the electronic part to cause a short circuit between electrodes.

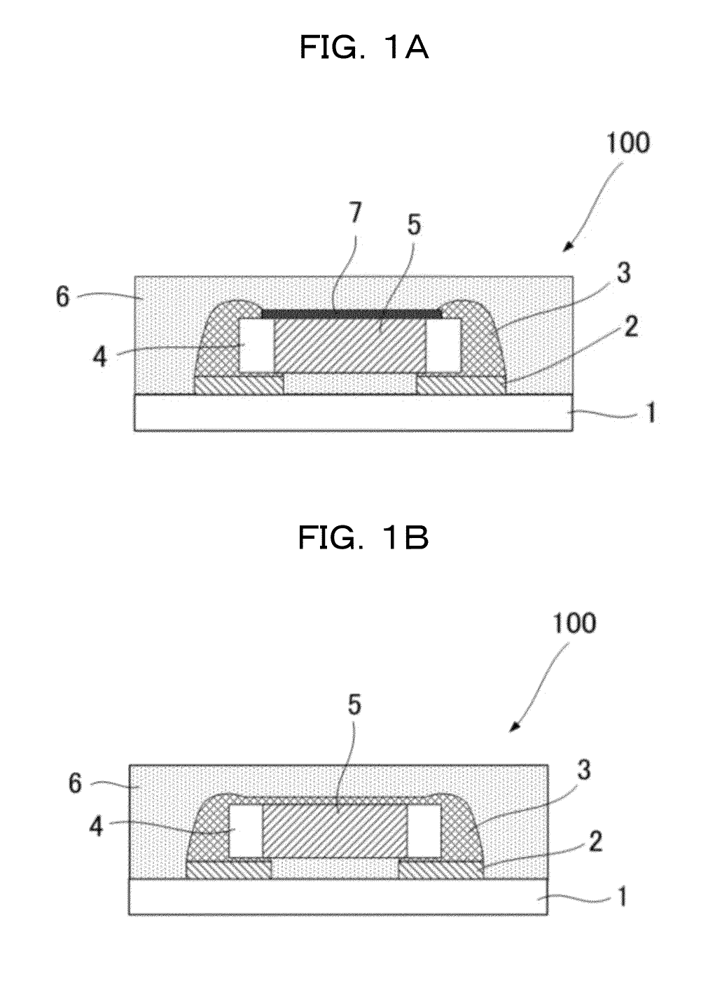

Use of a known conductive bonding material containing first metal particles having no pore will be described below with reference to FIGS. 1A and 1B.

As illustrated in FIG. 1A, an electronic part 100 includes a circuit board 1, an electrode pad 2 on the circuit board 1, a conductive bonding material 3, a component (for example, a chip component) 5 connected to the circuit board 1 through the conductive bonding material 3, electrodes 4 of the component 5, and a sealing resin 6 for sealing the component 5. When the electronic part 100 is connected to a large circuit board, such as a motherboard or a system board, by second reflow heating, volume expansion and the resulting stress caused by the re-melting of the conductive bonding material 3 may deform the sealing resin 6, causing a crack in the sealing resin 6 or a narrow gap 7 between the component 5 and the sealing resin 6. As illustrated in FIG. 1B, the re-melted conductive bonding material 3 may enter the gap 7 because of capillarity to electrically connect the electrodes 4 of the component 5 or the electrodes 4 of adjacent components 5, thereby causing a short circuit (hereinafter also referred to as a “flash phenomenon”).

A conductive bonding material according to one embodiment can reduce the flash phenomenon by using, as a solder component, a combination of first metal particles having at least one pore and second metal particles or coated particles, which are first metal particles having at least one pore coated with a second metal.

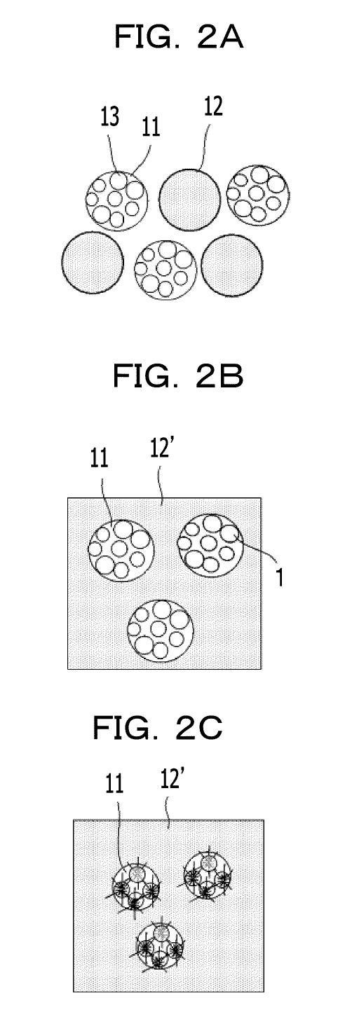

In the case that the solder component contains a combination (mixture) of first metal particles having at least one pore and second metal particles, as illustrated in FIG. 2A, the conductive bonding material just applied to an electrode pad on a circuit board, for example, by printing contains a mixture of first metal particles 11 having pores 13 and second metal particles 12, which have a lower melting point than the first metal (initial state). As illustrated in FIG. 2B, first reflow heating melts the second metal particles 12, and the first metal particles 11 are surrounded by the melted second metal 12′ (first reflow heating state). As illustrated in FIG. 2C, second reflow heating melts the first metal particles 11. The melted first metal enters the pores 13, which are under reduced pressure or vacuum, and fills the pores 13 of the first metal particles. This reduces the volume of the first metal particles and reduces the outward stress applied to the melted second metal 12′ surrounding the first metal particles having a reduced volume, thereby reducing the flash phenomenon. The pores 13 of the first metal particles 11 disappear after the second reflow heating.

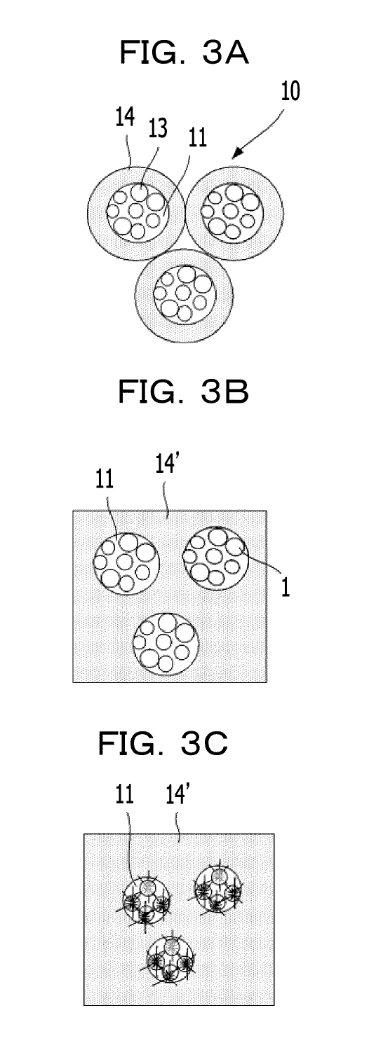

In the case that the solder component contains coated particles, which are first metal particles having at least one pore coated with a second metal, as illustrated in FIG. 3A, the conductive bonding material just applied to an electrode pad on a circuit board, for example, by printing contains coated particles 10, which are first metal particles 11 having pores 13 covered with a second metal layer 14 (initial state). As illustrated in FIG. 3B, first reflow heating melts the second metal layer 14 on the first metal particles 11, and the first metal particles 11 having the pores 13 under reduced pressure or vacuum are surrounded by the melted second metal 14′ (first reflow heating state). As illustrated in FIG. 3C, second reflow heating melts the first metal particles 11. The melted first metal enters the pores 13, which are under reduced pressure or vacuum, and fills the pores 13 of the first metal particles. This reduces the volume of the first metal particles and reduces the outward stress applied to the melted second metal 14′ surrounding the first metal particles having a reduced volume, thereby reducing the flash phenomenon. The pores 13 of the first metal particles 11 disappear after the second reflow heating.

A conductive bonding material according to one embodiment can reduce volume expansion and the resulting stress caused by the melting of the conductive bonding material in second reflow heating and reduce the flash phenomenon by using, as a solder component, a combination of first metal particles having at least one pore and second metal particles or coated particles, which are first metal particles having at least one pore coated with a second metal. Thus, the conductive bonding material can be widely used in various fields and is suitable for a method for producing a conductive bonding material for use in embodiments described below, an electronic part according to one embodiment, an electronic device according to one embodiment, a method for manufacturing an electronic part using the conductive bonding material, and a method for manufacturing an electronic device using the conductive bonding material.

<Method for Producing Conductive Bonding Material>

A method for producing a conductive bonding material for use in the embodiments discussed herein includes a process of producing first metal particles, a combining process, and an optional process.

<<Process of Producing First Metal Particles>>

A process of producing first metal particles according to a first embodiment includes melting a first metal, foaming the melted first metal under vacuum to form pores, cooling the first metal to form a first metal body having pores, cutting the first metal body under vacuum, and carrying out a tumbling fluidized bed process for the first metal body to form first metal particles.

A process of producing first metal particles according to a second embodiment includes forming a first metal body by an electroplating method, activating the surface of the first metal body, oxidizing the activated first metal body, and repeatedly pulverizing the oxidized first metal body to form first metal particles having at least one pore.

In the second embodiment, the surface of the first metal body formed by the electroplating method is activated, the activated first metal body is oxidized, and the oxidized first metal body is pulverized twice or more, preferably twice to 10 times.

In the first embodiment, the first metal particles may be produced by a foam melting method described below.

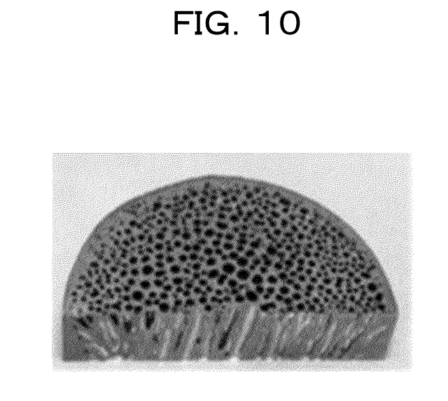

First, the first metal is melted at a temperature higher than the melting point of the first metal. If desired, a thickener, such as Ca, is added to increase the viscosity of the melted first metal. The melted first metal is then mixed with a foaming agent, such as TiH₂. The mixture is cooled to produce foam. The foam is cut into a size of approximately 50 μm. The cut foam is made spherical by tumbling fluidized bed process. Thus, the first metal particles having at least one pore are produced (see FIG. 10). The foaming agent may be a gas.

In the second embodiment, the first metal particles may be produced by the following method.

First, a first metal powder having a volume-average particle size of 10 μm is formed by an electroplating method. The first metal powder is then oxidized. The oxidized first metal powder is pulverized to a volume-average particle size in the range of 3 to 4 μm in a vacuum jet mill.

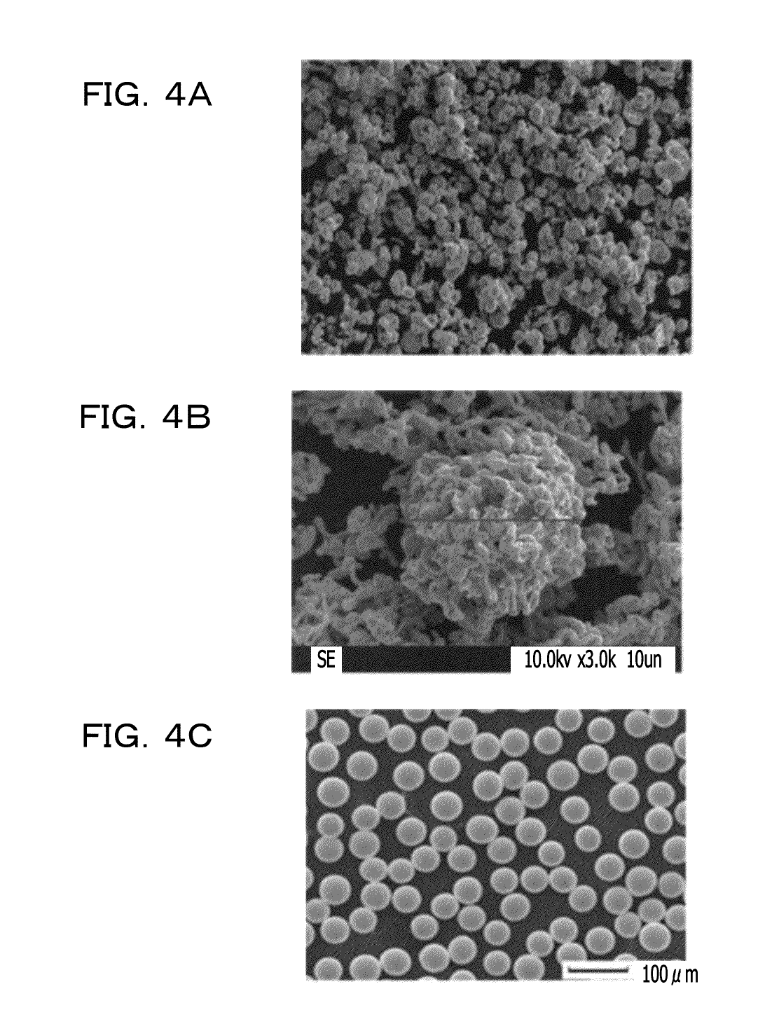

The surface of the first metal powder is then activated in a reducing atmosphere, such as a hydrogen atmosphere. The first metal powder having an activated surface coagulates to a volume-average particle size in the range of 10 to 20 μm. The coagulated first metal powder is then oxidized. The oxidized first metal powder is pulverized to a volume-average particle size in the range of 5 to 6 μm in a vacuum jet mill. The surface of the first metal powder is then activated in a reducing atmosphere, such as a hydrogen atmosphere. The first metal powder having an activated surface coagulates to a volume-average particle size in the range of 10 to 20 μm. The first metal powder is then oxidized again. The oxidized first metal powder is pulverized to a volume-average particle size in the range of 5 to 6 μm in a vacuum jet mill. These treatments may be repeatedly performed to form a porous first metal powder (see FIGS. 4A and 4B).

The first metal powder is supplied to an atomizer equipped with a pretreatment unit for feeding the powder through a melting nozzle. The surface of the first metal powder is melted and sealed under reduced pressure, and the volume-average particle size of the first metal powder is made uniform. Thus, the first metal particles are produced (see FIG. 4C). The first metal particles having a target volume-average particle size are then collected with a classifier. Thus, the first metal particles having at least one pore are produced.

<<Combining Process>>

The combining process includes combining the first metal particles with a second metal having a melting point lower than the melting point of the first metal particles.

The combining method includes a combination (mixture) of the first metal particles and the second metal particles or coated particles, which are the first metal particles coated with the second metal.

In the case of the combination (mixture) of the first metal particles and the second metal particles, the mass ratio (A:B) of the first metal particles (A) to the second metal particles (B) is preferably in the range of 20:80 to 50:50, more preferably 30:70 to 50:50.

In the case of the coated particles, which are the first metal particles coated with the second metal, the second metal layer preferably has an average thickness of 5 μm or more, more preferably in the range of 5 to 20 μm. A method for forming the second metal layer may be an electroless plating method.

<Optional Process>

The optional process is not particularly limited and may be appropriately selected for each purpose. For example, the optional process is a mixing process.

In the mixing process, the solder component, the flux component, and an optional component are mixed to prepare a conductive bonding material.

Mixing in the mixing process is not particularly limited and may be appropriately selected for each purpose. For example, the mixing is performed in a non-oxidizing atmosphere with a mixer or an agitator.

Electronic Part

An electronic part according to one embodiment includes a circuit board, a component, a sealing resin, a terminal, and an optional member.

The circuit board includes an electrode pad. The component includes a plurality of electrodes. The plurality of electrodes of the component are connected to the electrode pad of the circuit board using a conductive bonding material according to one embodiment.

<Circuit Board>

The shape, structure, and size of the circuit board are not particularly limited and may be appropriately selected for each purpose. For example, the circuit board is a plate. The circuit board may have a monolayer structure or a multilayer structure. The size of the circuit board may depend on the size of the electronic part.

The substrate of the circuit board is not particularly limited and may be appropriately selected for each purpose. Examples of the substrate include inorganic substrates, such as glass substrates, quartz substrates, silicon substrates, and silicon substrates covered with a SiO₂ film, and polymer substrates, such as epoxy substrates, phenol substrates, poly(ethylene terephthalate) substrates, polycarbonate substrates, polystyrene substrates, and poly(methyl methacrylate) substrates. These substrates may be used alone or in combination. Among these, glass substrates, quartz substrates, silicon substrates, silicon substrates covered with a SiO₂ film are preferred, and silicon substrates and silicon substrates covered with a SiO₂ film are particularly preferred.

The substrate may be appropriately synthesized or may be a commercial product.

The average thickness of the substrate is not particularly limited and may be appropriately selected for each purpose. The average thickness of the substrate is preferably 100 μm or more, more preferably 500 μm or more.

The size of the circuit board is not particularly limited and may be appropriately selected for each purpose. The circuit board is preferably in the range of 10 to 200 mm in length, 10 to 200 mm in width, and 0.5 to 5 mm in thickness.

The shape of a mounting face of the circuit board for the component is not particularly limited and may be appropriately selected for each purpose. For example, the mounting face is square, rectangular, or circular.

The circuit board is preferably a wiring circuit board that has a wiring pattern of a plurality of electrodes on the substrate.

The wiring circuit board is not particularly limited and may be appropriately selected for each purpose. For example, the wiring circuit board is a monolayer circuit board (monolayer printed wiring board) or a multilayer circuit board (multilayer printed wiring board).

A metal layer is formed on the electrodes of the circuit board, for example, by plating or lamination.

The metal layer may be made of Cu, Ag, Au, Ni, Sn, Al, Ti, Pd, or Si, preferably Cu, Ag, or Au.

When the conductive bonding material is applied to the electrodes on the circuit board, in order to improve the connection between the conductive bonding material and the electrodes on the circuit board, the surfaces of the electrodes on the circuit board are preferably coated. The surface coating is not particularly limited and may be appropriately selected for each purpose. For example, the surface coating is flux coating, pre-flux coating, metal plating, or soldering.

<Component>

The component is any component having a plurality of electrodes and may be appropriately selected for each purpose. For example, the component is a chip component or a semiconductor component.

The component is mounted on the circuit board. The chip component is not particularly limited and may be appropriately selected for each purpose. Examples of the chip component include capacitors and resistors. These chip components may be used alone or in combination.

The semiconductor component is not particularly limited and may be appropriately selected for each purpose. Examples of the semiconductor component include integrated circuits, large-scale integrated circuits, transistors, thyristors, and diodes. These semiconductor components may be used alone or in combination.

The size of the component is not particularly limited and may be appropriately selected for each purpose. For example, the component is of a 1608 type (1.6 mm×0.8 mm×0.8 mm), a 1005 type (1 mm×0.5 mm×0.5 mm), or a 0603 type (0.6 mm×0.3 mm×0.3 mm).

In general, a plurality of types of components are mounted on the circuit board. All the components are not necessarily connected by soldering. At least part of the components may be connected by soldering, and part of the components may be connected through a lead frame.

<<Application of Conductive bonding material>>

A method for applying the conductive bonding material to an electrode of the circuit board or a terminal of the electronic part is not particularly limited and may be appropriately selected for each purpose, provided that the conductive bonding material can be applied at a desired thickness or a desired weight. For example, the method for applying the conductive bonding material is a screen printing method, a transfer printing method, a dispense discharge method, or an ink jet method.

—Screen Printing Method—

The screen printing method may be performed with a printer having a mask.

The printer having a mask includes a unit for fixing a circuit board or an electronic part, a unit for aligning the mask with an electrode of the circuit board or a terminal of the electronic part, a unit for pressing the mask against the circuit board or the electronic part and applying a conductive bonding material according to one embodiment to the electrode of the circuit board or the terminal of the electronic part under the mask through an opening of the mask using a squeegee, and an optional unit.

The mask is not particularly limited and may be appropriately selected for each purpose. For example, the mask is a mesh mask or a metal mask. Among these, a metal mask is particularly preferred because the metal mask conforms to a wide variety of particle sizes and is easy to clean.

—Transfer Printing—

In accordance with the transfer printing method, a flat coating film having a certain thickness is formed from a conductive bonding material according to one embodiment using a squeegee at a certain clearance, the flat coating film is transferred to a stamper and is stamped on an electrode of a circuit board or a terminal of an electronic part to apply a certain amount of the conductive bonding material to the electrode of the circuit board or the terminal of the electronic part. A transfer printer may be used for transfer printing.

Such a transfer printer may include an applicator for forming a flat coating film, a fixing unit for fixing a circuit board, a transfer and stamp unit for three-dimensionally driving a stamper, transferring the flat coating film, and stamping the flat coating film, and an optional unit.

—Dispense Discharge Method—

In accordance with the dispense discharge method, a certain amount of a conductive bonding material according to one embodiment is discharged onto an electrode of a circuit board or a terminal of an electronic part. A dispenser may be used for the dispense discharge method.

Such a dispenser includes an injector for applying an on-demand discharge pressure to a conductive bonding material in a syringe to inject a certain amount of conductive bonding material through a needle at the tip of the syringe, a unit for three-dimensionally driving the syringe to align the syringe with an electrode of a circuit board or a terminal of an electronic part, a discharger for discharging a desired amount of conductive bonding material onto the electrode of the circuit board or the terminal of the electronic part, and an optional unit.

In accordance with the dispense discharge method, the discharge position and the discharge rate can be changed using a program. Thus, the conductive bonding material can be applied to a circuit board or an electronic part having a difference in level or recessed and raised portions against which a mask is difficult to press.

—Ink Jet Method—

In accordance with the ink jet method, a conductive bonding material according to one embodiment is discharged onto an electrode of a circuit board or a terminal of an electronic part through a fine nozzle of an ink jet apparatus.

The conductive bonding material on the electrode of the circuit board or the terminal of the electronic part is heated to a certain temperature for bonding.

An apparatus used for the bonding is not particularly limited and may be appropriately selected for each purpose. For example, the apparatus used for the bonding is a reflow apparatus having a furnace suitable for soldering heat treatment or a high-temperature bath.

Heat treatment using such a reflow apparatus is preferably performed at a temperature in the range of 100° C. to 300° C. for 10 to 120 minutes.

<Sealing Resin>

The sealing resin may be any resin that can seal the component and may be appropriately selected for each purpose. Examples of the sealing resin include thermosetting resins, such as phenolic resins, melamine resins, epoxy resins, and polyester resins.

A method for sealing the component is not particularly limited and may be appropriately selected for each purpose. For example, the method for sealing the component is potting for encapsulating the component with a thermosetting resin or transfer molding using a thermosetting resin.

Only the component may be sealed with the sealing resin, or the entire surface of the circuit board may be sealed with the sealing resin.

<Terminal>

The electronic part has a plurality of terminals. The terminals may be any terminals that can connect wires on the circuit board with an external substrate and may be appropriately selected for each purpose. For example, the terminals are lead wires.

The shape of the terminals is not particularly limited and may be appropriately selected for each purpose. For example, the terminals have a wire shape.

The material of such lead wires is not particularly limited and may be appropriately selected for each purpose. For example, the material of such lead wires is gold, silver, or copper.

Electronic Device

An electronic device according to one embodiment includes an electronic part and an optional member.

The electronic part may be an electronic part according to one embodiment. The electronic part is mounted on the electronic device by soldering a terminal of the electronic part to the electronic device using a conductive bonding material according to one embodiment.

The electronic device is not particularly limited and may be appropriately selected for each purpose. Examples of the electronic device include processors, such as personal computers and servers, communication devices, such as mobile phones and radio sets, office equipment, such as printers and copying machines, audio-visual equipment, such as television sets and audio systems, and household electrical appliances, such as air conditioners and refrigerators.

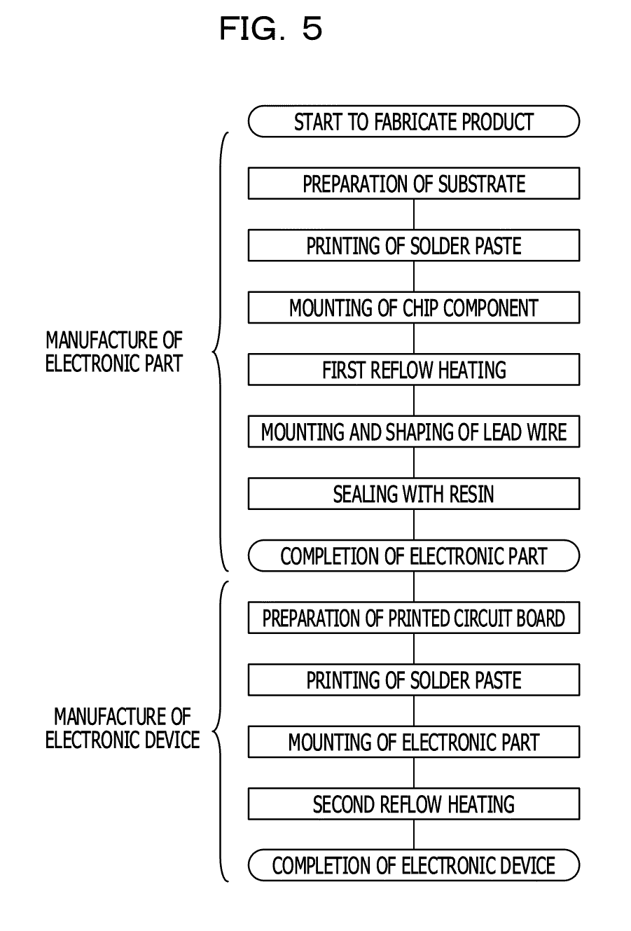

FIG. 5 is a flow chart of a method for manufacturing an electronic part according to one embodiment and a method for manufacturing an electronic device according to one embodiment.

<Method for Manufacturing Electronic Part Using Conductive Bonding Material>

A method for manufacturing an electronic device using a conductive bonding material according to one embodiment includes a process of producing first metal particles, a combining process, a substrate preparation process, a process of printing a solder paste as the conductive bonding material, a chip component mounting process, a first reflow heating process, a lead wire mounting and shaping process, a resin sealing process, and an optional process.

The process of producing first metal particles, the combining process, and the optional process are the same as in the method for producing a conductive bonding material and will not be further described.

—Substrate Preparation Process—

The substrate preparation process includes preparation of a circuit board having an electrode pad.

—Process of Printing Solder Paste—

The process of printing a solder paste includes printing a solder paste as a conductive bonding material according to one embodiment on the circuit board to apply the conductive bonding material to the electrode pad of the circuit board. The printing method is not particularly limited and may be appropriately selected for each purpose. For example, the printing method is screen printing.

—Chip Component Mounting Process—

The chip component mounting process includes mounting a component, such as a chip component, on the electrode pad of the circuit board.

—First Reflow Heating Process—

The first reflow heating process includes performing first reflow heating to solder a component, such as a chip component, on the circuit board. The first reflow heating is preferably performed at a peak temperature of 160° C. for 10 minutes.

—Lead Wire Mounting and Shaping Process—

The lead wire mounting and shaping process includes mounting and shaping a lead wire.

—Resin Sealing Process—

The resin sealing process includes sealing with a sealing resin. The sealing resin may be any resin that can seal the component and may be appropriately selected for each purpose. Examples of the sealing resin include thermosetting resins, such as phenolic resins, melamine resins, epoxy resins, and polyester resins.

Through these processes of the method for manufacturing an electronic part, the component is mounted on the circuit board (first mounting) to manufacture the electronic part.

<Method for Manufacturing Electronic Device Using Conductive Bonding Material>

A method for manufacturing an electronic device using a conductive bonding material according to one embodiment includes a process of producing first metal particles, a combining process, a printed circuit board preparation process, a process of printing a solder paste, a process of mounting an electronic part, a second reflow heating process, and an optional process.

The process of producing first metal particles, the combining process, and the optional process are the same as in the method for producing a conductive bonding material and will not be further described.

—Printed Circuit Board Preparation Process—

The printed circuit board preparation process includes preparation of a printed circuit board having a lead terminal.

—Process of Printing Solder Paste—

The process of printing a solder paste includes applying a solder paste as the conductive bonding material on the printed circuit board by screen printing, thereby applying the conductive bonding material to the lead terminal.

—Process of Mounting Electronic Part—

The process of mounting an electronic part includes placing a lead wire of the electronic part on the lead terminal of the printed circuit board.

—Second Reflow Heating Process—

The second reflow heating process includes second reflow heating. The electronic part is soldered to the printed circuit board (second mounting). The second reflow heating is preferably performed at a peak temperature of 235° C. for 5 minutes.

Through these processes of the method for manufacturing an electronic device, the electronic part is mounted on the printed circuit board (second mounting) to manufacture the electronic device.

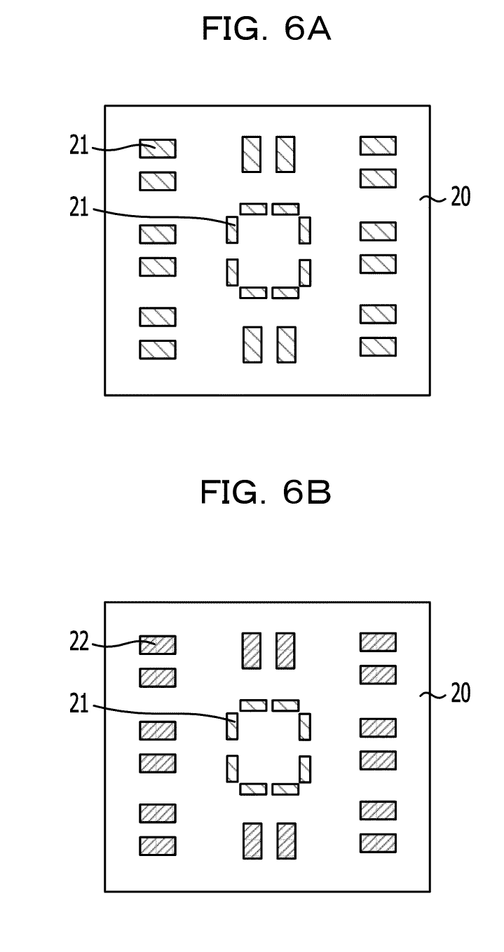

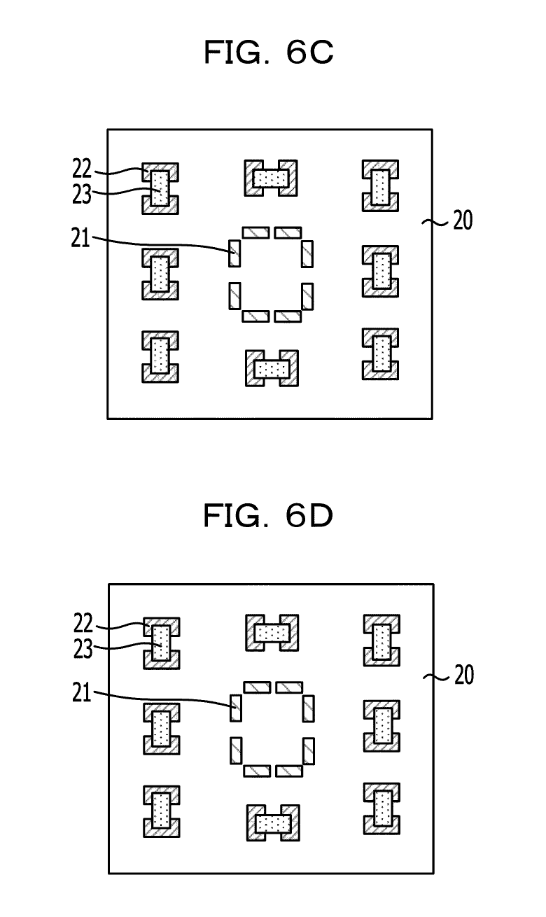

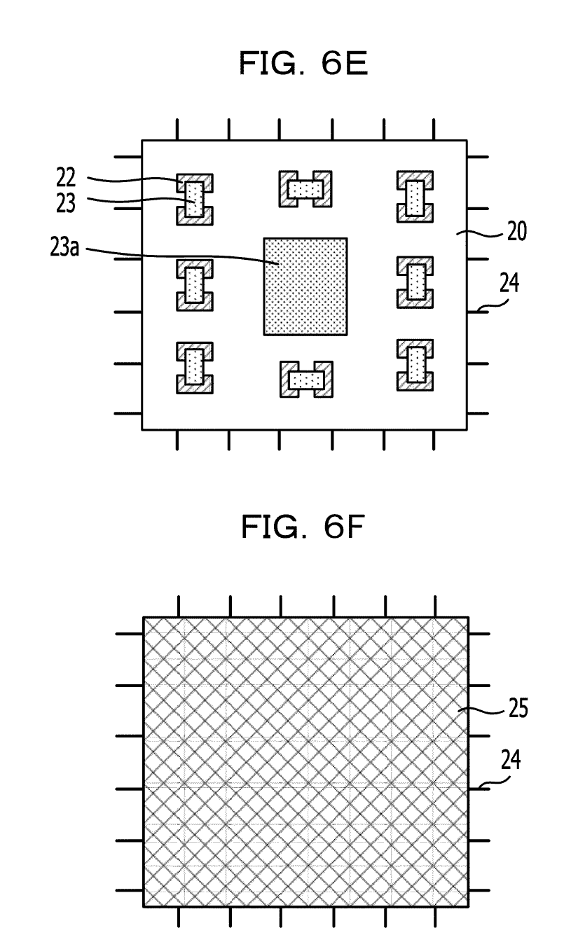

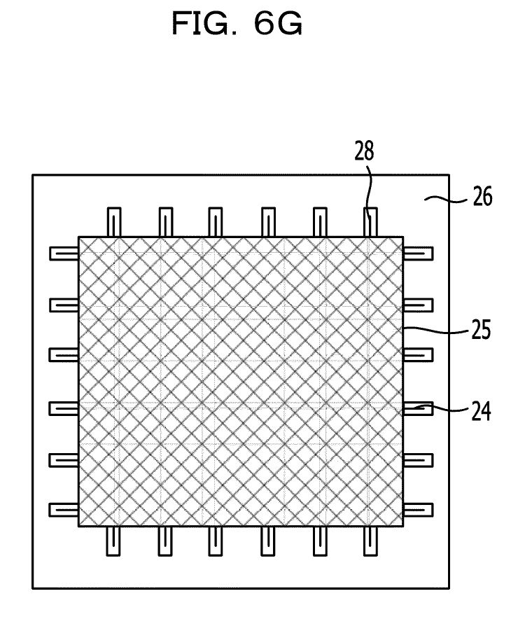

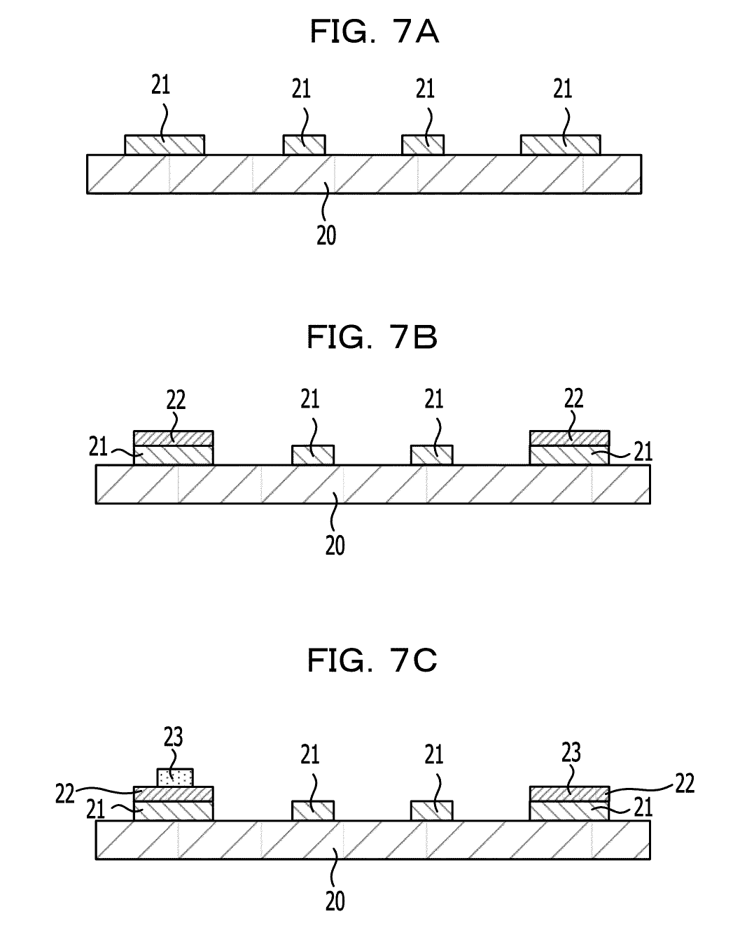

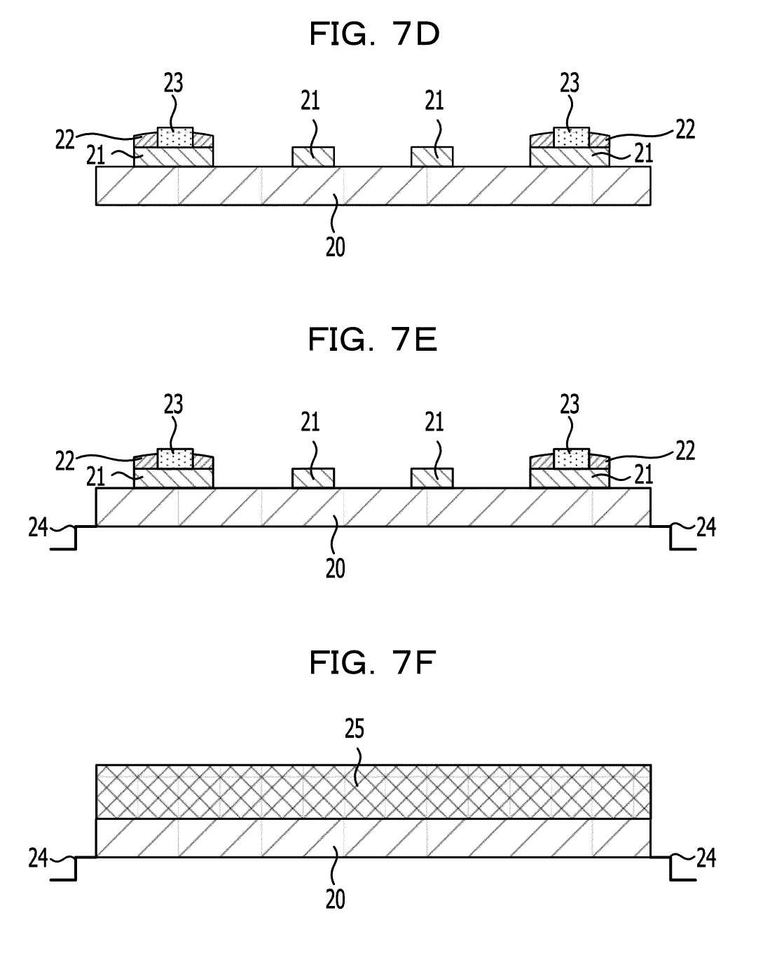

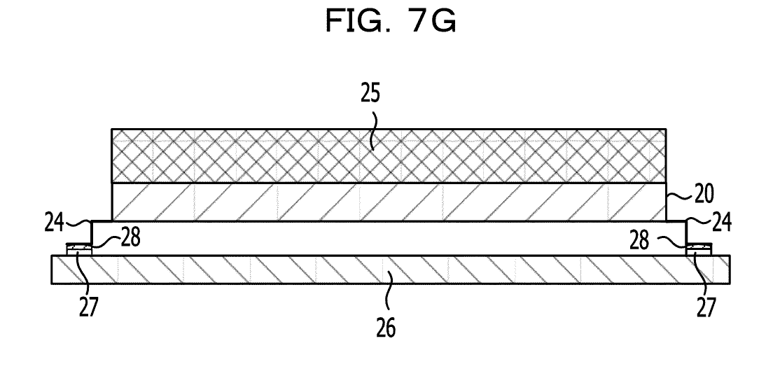

FIGS. 6A to 6G are schematic top views illustrating a method for manufacturing an electronic part according to one embodiment and a method for manufacturing an electronic device according to one embodiment. FIGS. 7A to 7G are schematic cross-sectional view illustrating a method for manufacturing an electronic part according to one embodiment and a method for manufacturing an electronic device according to one embodiment.

Referring to FIGS. 6A to 6G and FIGS. 7A to 7G, a method for manufacturing an electronic part according to one embodiment and a method for manufacturing an electronic device according to one embodiment will be described below.

First, as illustrated in FIGS. 6A and 7A, a circuit board 20 having electrode pads 21 is prepared.

As illustrated in FIGS. 6B and 7B, a solder paste is printed on the circuit board 20 as a conductive bonding material 22 according to one embodiment so as to apply the conductive bonding material 22 to part of the electrode pads 21. The printing method is not particularly limited and may be appropriately selected for each purpose. For example, the printing method is screen printing.

As illustrated in FIGS. 6C and 7C, a plurality of components 23 are placed on the conductive bonding material 22, which is disposed on part of the electrode pads 21.

As illustrated in FIGS. 6D and 7D, the components 23 are soldered by first reflow heating. The first reflow heating is preferably performed at a peak temperature of 160° C. for 10 minutes.

As illustrated in FIGS. 6E and 7E, if desired, another component 23a is mounted, and lead wires 24 are mounted and, if desired, shaped.

As illustrated in FIGS. 6F and 7F, sealing with a sealing resin 25 completes the mounting of the components 23 (first mounting). Thus, the electronic part according to the present embodiment is manufactured.

The sealing resin may be any resin that can seal the component and may be appropriately selected for each purpose. Examples of the sealing resin include thermosetting resins, such as phenolic resins, melamine resins, epoxy resins, and polyester resins.

As illustrated in FIGS. 6G and 7G, a printed circuit board 26 having lead terminals 27 is prepared. A solder paste is applied to the printed circuit board 26 by screen printing so as to apply a conductive bonding material 28 to the lead terminals 27. The lead wires 24 of the electronic part are placed on the lead terminals 27 of the printed circuit board 26. The electronic part is soldered to the printed circuit board 26 by second reflow heating (second mounting). The second reflow heating is preferably performed at a peak temperature of 235° C. for 5 minutes. Thus, the electronic device according to the present embodiment is manufactured.

### EXAMPLES

Although the embodiments discussed herein will be further described in the following examples, the embodiments are not limited to these examples.

In the following examples and comparative examples, the volume-average particle sizes of first metal particles and second metal particles, the average thickness of a second metal layer of coated particles, and the melting points of the first metal particles and the second metal particles were measured as described below.

<Method for Measuring Volume-Average Particle Sizes of First Metal Particles and Second Metal Particles>

The volume-average particle size of the metal particles was calculated from the particle size distribution of a population measured with a laser scattering diffraction particle size distribution analyzer (CILAS 1090, manufactured by Cilas).

<Method for Measuring Average Thickness of Second Metal Layer of Coated Particles>

The average thickness of a second metal layer was measured by an X-ray fluorescence analysis method (a fluorescent X-ray plating thickness measuring apparatus, manufactured by Alex Corp.).

<Method for Measuring Melting Points of First Metal Particles and Second Metal Particles>

The melting point of metal particles was measured with a differential scanning calorimeter (DSC) (DSC 6200, manufactured by Seiko Instruments Inc.) at a temperature gradient of 0.5° C./s in the temperature range of 25° C. to 250° C.

### Production Example 1

—Production of First Metal Particles Having Pores—

First metal particles having at least one pore, Sn-3.0Ag-0.5Cu alloy particles, were produced by the following method.

First, a Sn-3.0Ag-0.5Cu alloy powder having a volume-average particle size of 10 μm was formed by an electroplating method. The Sn-3.0Ag-0.5Cu alloy powder was oxidized. The oxidized Sn-3.0Ag-0.5Cu alloy powder was then pulverized to a volume-average particle size in the range of 3 to 4 μm in a vacuum jet mill.

The surface of the Sn-3.0Ag-0.5Cu alloy powder was activated in a hydrogen atmosphere. The Sn-3.0Ag-0.5Cu alloy powder having an activated surface coagulated to a volume-average particle size in the range of 10 to 20 μm. The coagulated Sn-3.0Ag-0.5Cu alloy powder was then oxidized. The oxidized Sn-3.0Ag-0.5Cu alloy powder was then pulverized to a volume-average particle size in the range of 5 to 6 μm in a vacuum jet mill. The surface of the pulverized Sn-3.0Ag-0.5Cu alloy powder was activated in a hydrogen atmosphere. The Sn-3.0Ag-0.5Cu alloy powder having an activated surface coagulated to a volume-average particle size in the range of 10 to 20 μm. The coagulated Sn-3.0Ag-0.5Cu alloy powder was then oxidized. The oxidized Sn-3.0Ag-0.5Cu alloy powder was then pulverized in a vacuum jet mill to a volume-average particle size in the range of 5 to 6 μm to produce a porous Sn-3.0Ag-0.5Cu alloy powder (see FIGS. 4A and 4B).

The Sn-3.0Ag-0.5Cu alloy powder was supplied to an atomizer having a pretreatment unit for feeding the powder through a melting nozzle. The surface of the first metal powder was melted and sealed under reduced pressure, and the volume-average particle size of the Sn-3.0Ag-0.5Cu alloy powder was made uniform. Thus, the Sn-3.0Ag-0.5Cu alloy particles were produced (see FIG. 4C). The Sn-3.0Ag-0.5Cu alloy particles having a target volume-average particle size were then collected with a classifier. Thus, Sn-3.0Ag-0.5Cu alloy particles having at least one pore (having a melting point of 217° C., a volume-average particle size of 40 μm, and a pore diameter of 20 μm) were produced.

### Production Example 2

—Production of Sn-3.0Ag-0.5Cu Alloy Particles Without Pores—

Melted Sn-3.0Ag-0.5Cu alloy was formed into particles by an atomizing method. The Sn-3.0Ag-0.5Cu alloy particles were cooled and collected. The Sn-3.0Ag-0.5Cu alloy particles were classified into a desired particle size range through a sifter. Thus, Sn-3.0Ag-0.5Cu alloy particles (having a melting point of 217° C. and a volume-average particle size of 40 μm) according to Production Example 2 were produced.

### Production Example 3

—Production of Second Metal Particles—

Melted Sn-57.0Bi-1.0Ag alloy was formed into particles by an atomizing method. The Sn-57.0Bi-1.0Ag alloy particles were cooled and collected. The Sn-57.0Bi-1.0Ag alloy particles were classified into a desired particle size range through a sifter. Thus, Sn-57.0Bi-1.0Ag alloy particles (having a melting point of 139° C. and a volume-average particle size of 40 μm) were produced as second metal particles.

### Production Example 4

—Production of Coated Particles—

Sn-3Ag-0.5Cu alloy particles having at least one pore (having a melting point of 217° C., a volume-average particle size of 30 μm, and a pore diameter of 20 μm) were produced as first metal particles in the same manner as in Production Example 1.

The Sn-3Ag-0.5Cu alloy particles having at least one pore were immersed in a plating bath that contained an electroless plating solution of a Sn-57.0Bi-1.0Ag alloy. A Sn-57.0Bi-1.0Ag alloy plating film having a thickness of 10 μm was formed, and the coated particles were washed and dried. Thus, the coated particles according to Production Example 4 were produced.

### Example 1

The following components were mixed in a non-oxidizing atmosphere to prepare a solder paste as a conductive bonding material.

<Flux component: 10% by Mass>

Polymerized rosin (pine resin): 48% by mass

Diphenylguanidine HBr (activator): 2% by mass

Hydrogenated castor oil (thixotropic agent): 5% by mass

Dibromohexane (aliphatic compound): 5% by mass α-terpineol (solvent): 40% by mass

<Solder Component: 90% by Mass>

<<First Metal Particles: 50% by Mass>>

The first metal particles having at least one pore produced in Production Example 1 were used.

Composition of first metal particles: Sn-3.0Ag-0.5Cu (% by mass)

Volume-average particle size: 40 μm

Average volume: 33510.32 μm3

Melting point: 217° C.

Definition of a pore: a portion (volume) without first metal in a first metal particle

Pore volume: 12.5% by volume (pore diameter 20 μm, first metal particle diameter 40 μm)

(4188.79020 μm3/33510.32 μm3)×100=12.5% by volume

Thermal expansion coefficient: 23.4 ppm/° C.

Volume expansion at 250° C.: 505.18 μm3

<<Second Metal Particles: 50% by Mass>>

The second metal particles produced in Production Example 3 were used.

Composition of second metal particles: Sn-57.0Bi-1.0Ag (% by mass)

Volume-average particle size: 40 μm

Average volume: 33510.32 μm3

Melting point: 139° C.

Thermal expansion coefficient: 15.0 ppm/° C.

Volume expansion at 250° C.: 327.78 μm3

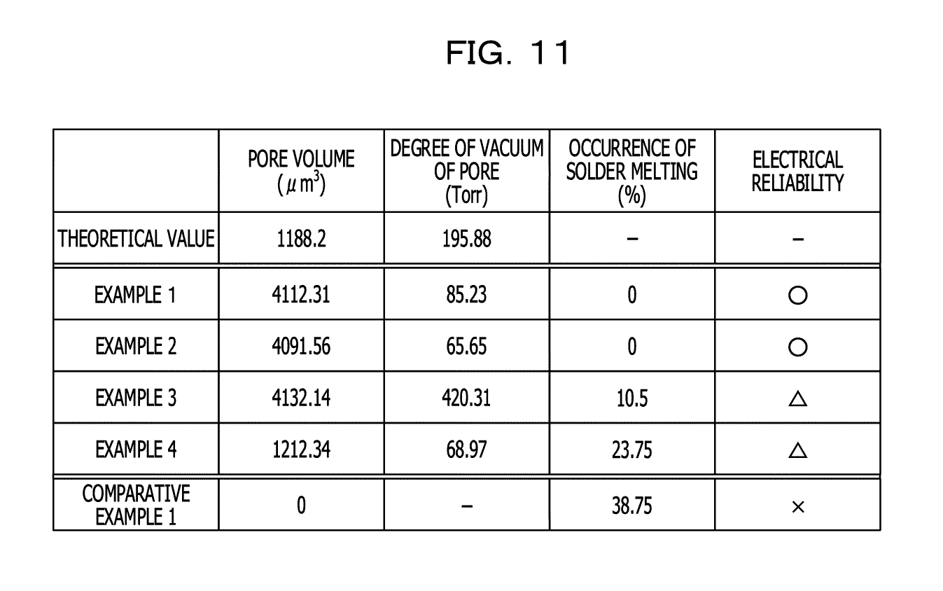

The pore volume and the degree of vacuum of the pore in the conductive bonding material thus prepared were measured as described below. The occurrence of solder melting and electrical reliability was evaluated as described below. FIG. 11 lists the results.

<Method For Measuring Pore Volume>

First, the volume of the solder component (the first metal particles and the second metal particles) before melting was calculated. The volume of the solder component (the first metal particles and the second metal particles) after melting was measured. The pore volume was calculated from these volumes using the following formula. The pore volume was the average of 10 measurements.

Pore volume (μm3)=Volume of solder component before melting−Volume of solder component after melting

<Method for Measuring Degree of Vacuum of Pore>

The solder component (the first metal particles and the second metal particles) was melted in a vacuum at 10-7 Torr. The number of moles was measured before and after the melting of the solder component (the first metal particles and the second metal particles). The increase in the number of moles (the number of moles in the pore) was calculated using an equation of state. The degree of vacuum of the pore was then calculated. The degree of vacuum of the pore was the average of 10 measurements.

Degree of vacuum of pore (Torr)=760 Torr/(number of moles in pore/number of moles under atmospheric pressure)

<Calculation of Theoretical Increased Volume Caused by Thermal Expansion of Solder Component in Second Reflow Heating>

The increased length δL of a first metal particle (having a diameter of 40 μm) having at least one pore caused by thermal expansion in second reflow heating can be calculated using the following formula.

Diameter of first metal particle at normal temperature (25° C.)×thermal expansion coefficient×temperature increase from normal temperature=diameter of first metal particle in second reflow heating

The thermal expansion coefficient of the first metal particle is 25 ppm/° C., and the second reflow heating temperature is a peak temperature of 260° C. (normal temperature: 25° C.).

Increased length δL of first metal particle caused by thermal expansion=40 μm×(25×10-6)×(260-25)=0.235 μm

The increased volume δV of the first metal particle having at least one pore caused by thermal expansion in second reflow heating can be calculated using the following formula.

Volume of first metal particle after thermal expansion (diameter 40 μm+0.235 μm=40.235 μm)−Volume of first metal particle before thermal expansion (diameter 40 μm)

Increased volume δV of first metal particle caused by thermal expansion=34104.42 μm3-33510.32 μm3=594.1 μm3

Increased volume δV of solder component caused by thermal expansion=594.1 μm3×2 (first metal particle+second metal particle)=1188.2 μm3

<Calculation of Theoretical Degree of Vacuum of Pore in First Metal Particle Having Pore>

The force that minimizes the surface area of melted first metal can be calculated from the pressure difference using the following Laplace's equation assuming the moment when liquid has a curved surface.

<<Laplace's Equation>>

Pressure difference δP=P(air)−P(liquid)

wherein P(air) is substantially zero.

The cohesive force of melted first metal is 50,000 Pa at 250° C.

The degree of vacuum of the pore causing a pressure less than or equal to the cohesive force of the melted first metal at 250° C. (50,000 Pa) is determined.

If the first metal particle has a pore diameter of 20 μm, the pore volume is 4188.79 μm3=4.18879×10-12 liter.

The number of moles at a degree of vacuum of 760 Torr (the atmospheric pressure) is 4.18879×10-12 liter/22.4 liter.

Using these values, the degree of vacuum (Torr) is calculated in accordance with the Boyle-Charles law from the number of moles at which the cohesive force of the first metal at 250° C. is 50,000 Pa or less.

<<Boyle-Charles law>>

P(50,000 Pa)=(n/V)RT (523 K)

The degree of vacuum of the pore in equilibrium with the cohesive force of the first metal of 50,000 Pa at 250° C. is 195.88 Torr.

<Method for Evaluating Occurrence of Solder Melting (Flash Phenomenon)>

A copper pattern (pad size: 0.3 mm in length×0.3 mm in width, distance between pads (pitch): 0.2 mm) was formed on a circuit board (110 mm in length×110 mm in width×1.0 mm in thickness).

The conductive bonding material was screen-printed on the circuit board using a metal screen and a metal squeegee. A chip component (a 0603 chip component (0.6 mm in length×0.3 mm in width×0.3 mm in thickness), a Sn electrode) was placed on the screen-printed conductive bonding material. The chip component was subjected to first reflow heating in a non-oxidizing atmosphere (oxygen concentration of less than 100 ppm) at a peak temperature of 160° C. for 10 minutes for first mounting on the circuit board.

After the circuit board was washed, a sealing resin (epoxy adhesive) was applied to the circuit board, was cured at 150° C. for one hour, and was left to stand at high temperature and high humidity (85° C. and 85% RH) for 24 hours, thus producing an electronic part.

The electronic part was subjected to second re-flow heating at a peak temperature of 235° C. for 5 minutes (second mounting).

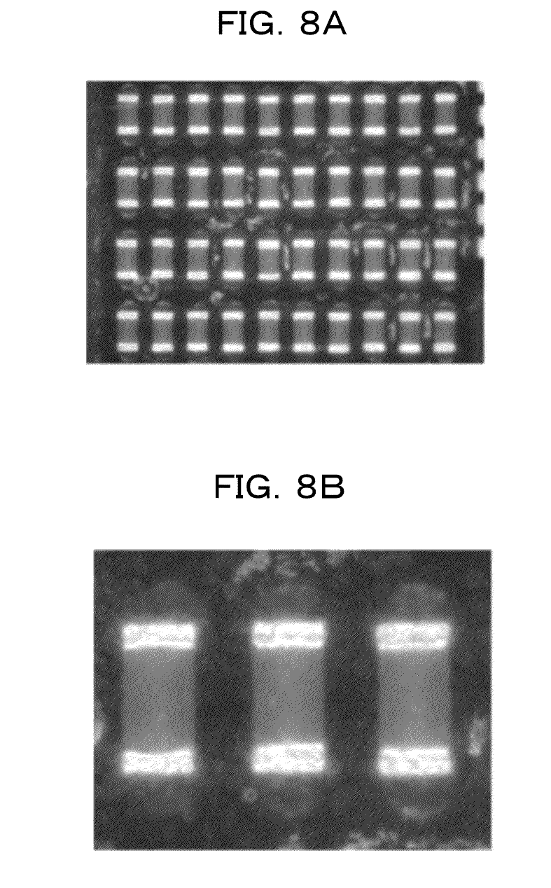

After the second re-flow heating, the electronic part was visually inspected. The number of chips having solder melting between and within chip components. The occurrence (%) was determined for 400 chip components. FIGS. 8A and 8B are photographs of the electronic parts after the second mounting evaluated in Example 1. As depicted in FIGS. 8A and 8B, no solder melting occurred in Example 1.

<Method for Evaluating Electrical Reliability>

In the same manner as in the method for evaluating the occurrence of solder melting, the electronic part was subjected to second re-flow heating at a peak temperature of 235° C. for 5 minutes (second mounting). After the second mounting, the electrical resistance of a soldered portion of the electronic part was measured with a resistance meter (77MULTIMETER manufactured by Fluke Corp.). The electrical reliability of the electronic part was evaluated in accordance with the following criterion.

[Evaluation Criterion]

Good (circle): no increase in electrical resistance

Fair (triangle): an increase in electrical resistance

Poor (cross): open fault

### Example 2

A conductive bonding material according to Example 2 was produced in the same manner as in Example 1 except that the coated particles produced in Production Example 4 were used as the solder component.

The pore volume and the degree of vacuum of the pore of the conductive bonding material were measured in the same manner as in Example 1. The occurrence of solder melting and electrical reliability was evaluated in the same manner as in Example 1. FIG. 11 lists the results.

### Example 3

A conductive bonding material according to Example 3 was produced in the same manner as in Example 1 except that the first metal particles were produced by changing the conditions for the manufacture of the first metal particles in Production Example 1. The first metal particles had the pore volume and the degree of vacuum of the pore listed in FIG. 11.

The pore volume and the degree of vacuum of the pore of the conductive bonding material were measured in the same manner as in Example 1. The occurrence of solder melting and electrical reliability was evaluated in the same manner as in Example 1. FIG. 11 lists the results.

### Example 4

A conductive bonding material according to Example 4 was produced in the same manner as in Example 1 except that the first metal particles were produced by changing the conditions for the manufacture of the first metal particles in Production Example 1. The first metal particles had the pore volume and the degree of vacuum of the pore listed in FIG. 11.

The pore volume and the degree of vacuum of the pore of the conductive bonding material were measured in the same manner as in Example 1. The occurrence of solder melting and electrical reliability was evaluated in the same manner as in Example 1. FIG. 11 lists the results.

### Comparative Example 1

A conductive bonding material according to Comparative Example 1 was produced in the same manner as in Example 1 except that the following solder component was used.

<Solder Component: 90% by Mass>

Sn-3Ag-0.5Cu alloy particles having no pore (having a melting point of 218° C. and a volume-average particle size of 40 μm) produced in Production Example 2: 50% by mass

Sn-57.0Bi-1.0Ag alloy particles (having a melting point of 139° C. and a volume-average particle size of 40 μm) produced as second metal particles in Production Example 3: 50% by mass

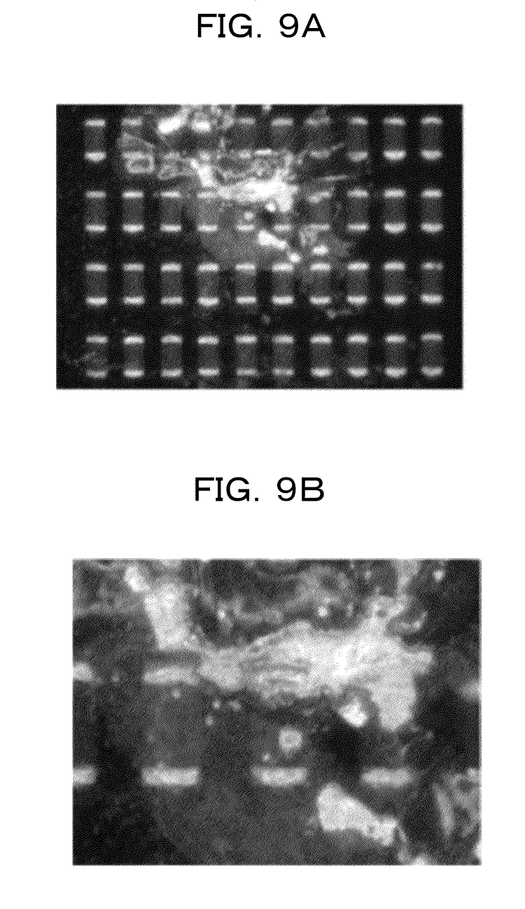

The pore volume and the degree of vacuum of the pore of the conductive bonding material were measured in the same manner as in Example 1. The occurrence of solder melting and electrical reliability was evaluated in the same manner as in Example 1. FIG. 11 lists the results. FIGS. 9A and 9B are photographs of the electronic parts after the second mounting evaluated in Comparative Example 1. FIGS. 9A and 9B indicate that solder melting occurred in Comparative Example 1.

In FIG. 11, the pore volume in Example 1 was 4112.31 μm3, which is larger than the theoretical increased volume caused by the thermal expansion of the solder component in the second reflow heating (1188.2 μm3). The degree of vacuum of the pore in Example 1 was 85.23 Torr, which is lower than the theoretical degree of vacuum of the pore (195.88 Torr). Thus, in Example 1, the pores of the first metal particles can sufficiently reduce the volume expansion and the resulting stress in the second reflow heating, and the occurrence of solder melting was 0%.

The pore volume in Example 2 was 4091.56 μm3, which is larger than the theoretical increased volume caused by the thermal expansion of the solder component in the second reflow heating (1188.2 μm3). The degree of vacuum of the pore in Example 2 was 65.65 Torr, which is lower than the theoretical degree of vacuum of the pore (195.88 Torr). Thus, in Example 2, the pores of the first metal particles can sufficiently reduce the volume expansion and the resulting stress in the second reflow heating, and the occurrence of solder melting was 0%.

The pore volume in Example 3 was 4132.14 μm3, which is larger than the theoretical increased volume caused by the thermal expansion of the solder component in the second reflow heating (1188.2 μm3). The degree of vacuum of the pore in Example 3 was 420.31 Torr, which is higher than the theoretical degree of vacuum of the pore (195.88 Torr). Thus, in Example 3, although the pores of the first metal particles can reduce the volume expansion and the resulting stress in the second reflow heating, a high degree of vacuum of the pore resulted in poor absorption of the melted first metal, and the occurrence of solder melting was 10.5%. This resulted in an increase in electrical resistance.

The pore volume in Example 4 was 1212.34 μm3, which is larger than the theoretical increased volume caused by the thermal expansion of the solder component in the second reflow heating (1188.2 μm3). The degree of vacuum of the pore in Example 4 was 68.97 Torr, which is lower than the theoretical degree of vacuum of the pore (195.88 Torr). Thus, in Example 4, the pores of the first metal particles insufficient reduced the volume expansion and the resulting stress in the second reflow heating, and the occurrence of solder melting was 23.75%. This resulted in an increase in electrical resistance.

In Comparative Example 1, the first metal particles having no pore could not reduce the volume expansion and the resulting stress in the second reflow heating, and the occurrence of solder melting was 38.75%. This resulted in the occurrence of an open fault and very low electrical reliability.

### Example 5

<Manufacture of Electronic Part and Electronic Device>

An electronic part and an electronic device were manufactured as described below using the conductive bonding material produced in Example 1.

<<Manufacture of Electronic Part>>

First, a copper pattern (pad size: 0.3 mm in length×0.3 mm in width, distance between pads (pitch): 0.2 mm) was formed on a circuit board (110 mm in length×110 mm in width×1.0 mm in thickness). The conductive bonding material produced in Example 1 was screen-printed on the circuit board using a metal screen and a metal squeegee. The metal screen had a pad opening of 100% and a thickness of 150 μm. A chip component (a 0603 chip component, a Sn electrode) was placed on the printed conductive bonding material. The chip component was subjected to first re-flow heating in a non-oxidizing atmosphere (oxygen concentration of less than 100 ppm) at a peak temperature of 160° C. for 10 minutes for first mounting on the circuit board.

After the circuit board was washed, a sealing resin (epoxy adhesive) was applied to the circuit board, was cured at 150° C. for one hour, and was left to stand at high temperature and high humidity (85° C. and 85% RH) for 24 hours, thus producing an electronic part. Lead wires were not connected.

<<Manufacture of Electronic Device>>

The conductive bonding material was screen-printed as a solder paste on a circuit board having lead terminals to apply the conductive bonding material to the lead terminals. The lead wires of the electronic part were placed on the lead terminals of the circuit board. The electronic part was soldered to the circuit board by second reflow heating at a peak temperature of 235° C. for 5 minutes. Thus, the electronic device was manufactured.

<<Evaluation>>

The occurrence of solder melting and the electrical reliability of the electronic device were evaluated in the same manner as in Example 1. The occurrence of solder melting was 0%, and no increase in electrical resistance was observed. Thus, the electronic device had high electrical reliability.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A conductive bonding material comprising:
a solder component including:
a metal foamed body of a first metal having at least one pore, the pore absorbs melted first metal when the metal foamed body is heated at a temperature higher than the melting point of the first metal, and
a second metal having a melting point lower than the melting point of the first metal.

2. The conductive bonding material according to claim 1, wherein
the solder component contains particles of the metal foamed body and particles of the second metal, or the solder component contains coated particles, which are particles of the metal foamed body coated with the second metal.

3. The conductive bonding material according to claim 2, wherein
the mass ratio (A:B) of the particles of the first metal (A) to the particles of the second metal (B) is in the range of 20:80 to 50:50.

4. The conductive bonding material according to claim 1, wherein
the first metal has a melting point of 150° C. or more and 230° C. or less, and the second metal has a melting point of less than 150° C.

5. The conductive bonding material according to claim 1, wherein
the metal foamed body of the first metal is one of Sn—Bi—X alloy particles and Sn—Cu—X alloy particles, X being selected from the group consisting of Ag, Ni, Zn, Pd, and In.

6. The conductive bonding material according to claim 1, wherein
the second metal is one of a Sn—Bi alloy and a Sn—Bi—Y alloy, Y being selected from the group consisting of Ag, Ni, Zn, Pd, and In.

7. The conductive bonding material according to claim 1, wherein
the solder component constitutes 50% by mass or more and 95% by mass or less of the conductive bonding material.

8. The conductive bonding material according to claim 1, further comprising a flux component made of at least one of an epoxy flux material and a rosin flux material.

9. The conductive bonding material according to claim 8, wherein the flux component constitutes 5% by mass or more and 50% by mass or less of the conductive bonding material.

10. A method of manufacturing a conductive bonding material comprising:
melting a first metal;
foaming the melted first metal under vacuum to form pores;
cooling the melted first metal to form a metal foamed body;
cutting the metal foamed body under vacuum;
carrying out a tumbling fluidized bed process for the cut metal foamed body to form first metal particles; and
combining the first metal particles with a second metal having a melting point lower than the melting point of the first metal particles.

11. The method of manufacturing the conductive bonding material according to claim 10, wherein
the conductive bonding material contains a solder component, the solder component containing the first metal particles and particles of the second metal, or the solder component containing coated particles, which are the first metal particles coated with the second metal.

12. The method of manufacturing the conductive bonding material according to claim 10, wherein
the first metal has a melting point of 150° C. or more and 230° C. or less, and the second metal has a melting point of less than 150° C.

13. The method of manufacturing the conductive bonding material according to claim 10, wherein
the first metal is one of Sn—Bi—X alloy particles and Sn—Cu—X alloy particles, X being selected from the group consisting of Ag, Ni, Zn, Pd, and In.

14. The method of manufacturing the conductive bonding material according to claim 10, wherein
the second metal is one of a Sn—Bi alloy and a Sn—Bi—Y alloy, Y being selected from the group consisting of Ag, Ni, Zn, Pd, and In.

15. The method of manufacturing the conductive bonding material according to claim 11, wherein
the solder component constitutes 50% by mass or more and 95% by mass or less of the conductive bonding material.

16. A method of manufacturing a conductive bonding material comprising:
forming a first metal body by an electroplating method;
activating the surface of the first metal body;
oxidizing the activated first metal body, and repeatedly pulverizing the oxidized first metal body to form first metal particles having at least one pore; and
combining the first metal particles with a second metal having a melting point lower than the melting point of the first metal particles.

17. A method of manufacturing an electronic device comprising:
applying a conductive bonding material to an electrode pad of a circuit board;
mounting a component over the electrode pad of the circuit board;
performing first reflow heating to heat the component with the circuit board;
mounting and shaping a lead wire to the component;
sealing the component with a sealing resin;
applying a solder paste to a lead terminal of a printed circuit board;
mounting resin sealed the component over the printed circuit board so as to the lead wire is placed on the lead terminal; and
performing second reflow heating to heat the component with the printed circuit board, wherein
the a conductive bonding material includes
a metal foamed body of a first metal having at least one pore, the pore absorbs melted first metal when the metal foamed body is heated at a temperature higher than the melting point of the first metal, and
a second metal having a melting point lower than the melting point of the first metal.

18. The method of manufacturing the electronic device according to claim 17, wherein
the first reflow heating is performed at a peak temperature of 160° C. for 10 minutes.

19. The method of manufacturing the electronic device according to claim 18, wherein
the second reflow heating is performed at a peak temperature of 235° C. for 5 minutes.
